(19) United States
(12) Patent Application Publication
(10) Pub. No.: US 2013/0146117 A1
(43) Pub. Date: Jun. 13, 2013

(54) System and Method for Converting Electromagnetic Radiation to Electrical Energy

(71) Applicant: Patrick K. Brady, Glen Ellyn, IL (US)

(72) Inventor: Patrick K. Brady, Glen Ellyn, IL (US)

(21) Appl. No.: 13/708,481

(22) Filed: Dec. 7, 2012

Related U.S. Application Data
(60) Provisional application No. 61/569,205, filed on Dec. 9, 2011.

(51) Int. Cl. H01L 35/02

(52) U.S. Cl. CPC H01L 35/02
USPC 136/201; 136/206

(57) ABSTRACT

An nanoantenna comprising a resonant structure element is tuned to capture energy, for example heat or light, radiated at a resonant frequency and to transfer structure to convert the captured energy to electrical energy. A co-planar strip can be used to provide impedance matching between the resonant structure element and the transfer structure. An array of nanoantennae form a nanoantenna array to provide electrical energy output from a plurality of nanoantennae. The nanoantenna array can be coupled to a device or apparatus as a power source.

This application claims the benefit of U.S. Provisional Application No. 61/569,205, filed Dec. 9, 2011, which is hereby incorporated by reference in its entirety.

### BACKGROUND

1. Field of the Invention

Embodiments of the present invention relate generally to structures and methods for harvesting energy from electromagnetic radiation and, more specifically, to nanostructures and related methods and systems for harvesting energy from, for example, infrared, near infrared and visible spectrums and capturing millimeter and Terahertz energy.

2. Background of the Invention

There is a great need for inexpensive renewable energy in the world right now. Ironically, there is an abundance of energy available in the form of sunlight and heat but using it to support the needs of society requires it to be converted into electrical form. Most electrical energy used today comes from a conversion process involving heat. Nuclear, coal, diesel, and natural gas powered electrical generation plants all convert stored forms of energy into heat for conversion into electricity. Processes in these plants are inefficient and often produce more heat as waste than is converted into electricity.

Harvesting sources of heat into usable electrical power is especially desirable at low cost. The cost of turbine based solutions is well established at this point. The presence of new technological solutions to conversion of heat to electrical power enter a relatively mature environment. Because of the need and the fixed pricing environment new technologies are beginning to address this area. Among the entrants are thermo photovoltaic (TPV), thermoelectric (TE) and organic rankine cycle (ORC).

TPV technology has had a difficult time making progress in heat conversion since photovoltaic (PV) converts short wave radiation and not the long waves found in the infrared (IR) and near IR. New micron gap methods of bringing this long wave energy to the PV cell still need conversion technology better suited to this influx of long wave radiation. The PV cell band gap favors only energetic photons since lower energy photons do not have the energy to surmount the gap and end up absorbed and cause heat in the PV cell.

Thermoelectric has only been able to convert heat to electrical power at low efficiency. To date TE has been unable to breakthrough to provide substantial efficiencies in energy conversion. Even so, TE has found application in automotive waste heat recovery speaking to the great need for alternative heat to electric conversion technologies.

Organic Rankine Cycle technology harvests waste heat by chaining turbines together with heat exchangers each with a lower boiling point liquid in its system. These systems are bulky and have large numbers of moving parts. They are also limited to the properties of the liquids and ultimately the limit of time, space and marginal results of additional systems in a working space.

### BRIEF SUMMARY OF THE INVENTION

The technology of surfaces of paired nanoantenna and diode arrays present tremendous advantages for energy harvesting applications. In the area of waste heat recovery these systems are ideal since they have no moving parts, are inexpensive to manufacture and can be tuned to frequency spectra of the target source. The ability to tune the collecting elements of the system to the spectral properties of the source make this ideal not only for waste heat applications but for heat harvesting in general and, ultimately, solar energy harvesting as well. For convenience of discussion the collector array components of these are systems are called Nanoantenna Electromagnetic Collector (NEC).

One embodiment of the present invention is an energy harvesting system. The basis for elements of this system are found in U.S. Pat. Nos. 7,792,644 and 6,534,784 B2 and U.S. Patent App. Pub. Nos. 2010/0284086 and 2006/0283539, each of which is included by reference herein in its entirety. The subject embodiment includes resonant elements tuned to frequencies in the range of available radiant energy. Typically, such frequencies are in the frequency range from approximately 10 THz, in the infrared, to over 1000 THz (visible light). These resonant elements are composed of electrically conductive material and coupled with a transfer element for conversion of stimulated electrical energy in the resonant element to direct current to form resonant and transfer element pairs. The resonant element and transfer element pairs are arranged into arrays that are embedded in a substrate and interconnected so as to form the source, for example, for an electrical circuit or other apparatus or device requiring sourced electrical energy to operate. In an embodiment, the resonant elements may be connected to the transfer elements through an impedance balancing technology, such as a co-planar strip transmission line (CPS) or other device or technology to balance the impedance between elements. Other methods of impedance matching may also be employed as discussed in detail below.

Also included is a ground plane of conductive material set a distance of a quarter wavelength from the resonance elements creating a resonance gap to reflect unabsorbed radiation back to the resonance elements. All components, elements and substrate of this embodiment are composed of metals and materials that allow them to be manufactured in low cost methods such as roll-to-roll.

In accordance with another embodiment of the present invention, another energy harvesting system is provided. This system includes a ground plane, a substrate, and resonant elements and transfer elements. In this system the resonant elements are tuned to frequencies in the IR or IR and near IR so that the system can harvest energy radiated from heat sources. The specific nature of heat harvesting environments may dictate high temperature tolerant substrate materials of limited flexibility that would alter the roll-to-roll production methods. This system may be used in any application to convert heat to electricity such as waste heat from coal power plants or even replacing the turbine in electrical generation applications.

In accordance with another embodiment of the present invention, another energy harvesting system is provided. This system includes a ground plane, a substrate, resonant elements and transfer elements. In this system the resonant elements are tuned to frequencies in the IR or IR and near IR so that the system can harvest from heat sources. In this embodiment the NEC system interfaces with conventional TPV systems to serve as their collectors for converting incoming long wave energy to electricity. In this embodiment the TPV system is considerably improved by the ability of the NEC system layer to convert the incoming emitter radiation in its spectral form. In one form of this embodiment there is no need for the filter layer since the NEC system is configured to harvest a wide spectrum. In other embodiments there may be some advantages to filtering some of the incoming spectral energy and reflecting it back to the emitter. In any case, the NEC layer radically reduces the material requirements on the TPV filter to significant advantage.

In accordance with another embodiment of the present invention, another energy harvesting system is provided. This system includes a ground plane, a substrate, resonant elements and transfer elements. In this system the resonant elements are tuned to frequencies in the IR or IR and near IR so that the system can harvest energy radiated from heat sources. In this embodiment the NEC system interfaces with conventional micron gap TPV (MTPV) systems to serve as their collectors for converting incoming long wave energy to electricity.

### BRIEF DESCRIPTION OF THE DRAWINGS

FIG. 1 is a schematic diagram illustrating antenna having a co-planar strip and diode according to an embodiment of the present invention.

FIG. 2 is a cross-section view of an exemplary antenna, substrate, and ground plane according to an embodiment of the present invention.

FIG. 3 is a cross-section view of an exemplary transfer structure connecting antenna segments according to an embodiment of the present invention.

FIG. 4 is a schematic diagram of an exemplary bus illustrating interconnecting elements of an array according to an embodiment of the present invention.

FIG. 5 is a schematic diagram of illustrating antenna having a co-planar strip connected by multiple transfer structures to reduce impedance/resistance.

FIG. 6 is a schematic illustration of an exemplary micron gap thermo photovoltaic device (MTPV) with a NEC layer for harvesting according to an embodiment of the present invention.

FIG. 7 illustrates using NEC harvesting material in a TPV device according to an embodiment of the present invention.

FIG. 8 is a schematic diagram of an exemplary overall system diagram for providing power to devices or apparatus using NEC film according to an embodiment of the present invention.

FIG. 9 is a view of an exemplary heat source and NEC film for heat harvesting according to an embodiment of the present invention.

FIG. 10 is a cross-section view of an exemplary diode region connecting resonant structure segments for a single layer diode composed of same material as antenna.

FIG. 11 is a cross section view of an exemplary diode region connecting resonant structure segments for a single layer diode composed of different material from antenna.

### DETAILED DESCRIPTION

The following description is presented to enable one of ordinary skill in the art to make and use the invention and is provided in the context of a patent application and its requirements. Various modifications to the described embodiments will be readily apparent to those skilled in the art and the generic principles herein may be applied to other embodiments. Thus, the present invention is not intended to be limited to the embodiments shown but is to be accorded the widest scope consistent with the principles and features described herein.

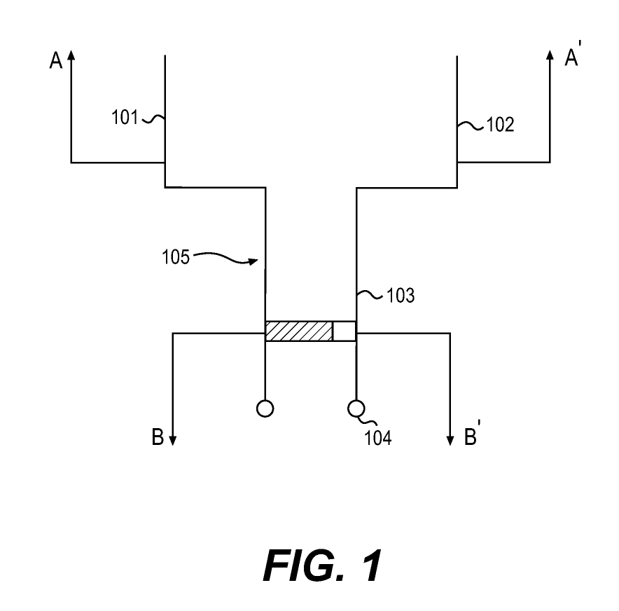

FIG. 1 is a schematic diagram illustrating antenna having a co-planar strip and diode according to an embodiment of the present invention. Referring to FIG. 1, a resonant structure according to an embodiment includes resonant structure components 101 and 102 (also referred to herein as resonant structure elements). In an embodiment, the resonant structure is an antenna or nanoantenna. Resonant structure components 101 and 102 are connected to a transfer structure 103 by a co-planar strip 105. Transfer structure 103 converts electrical energy stimulated by resonant structure components 101 and 102 to direct current. Co-planar strip 105 creates a mechanism to match impedance between the resonant structure elements 101 and 102 and the transfer structure 103.

The dimensions of the antennae or nanoantennae are selected in accordance with desired frequency range of interest. The materials and dimensions are selected by methods described in U.S. Pat. No. 7,792,644 and U.S. Patent App. Pub. No. 2010/0284086.

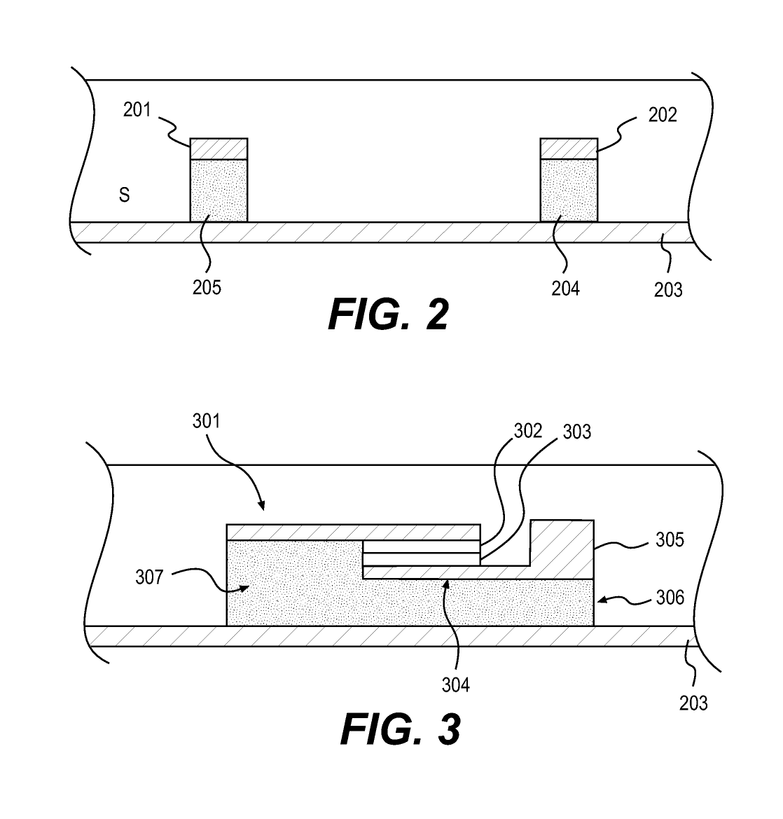

In one embodiment, the transfer structure is a metal double insulator metal diode (MIIM). An exemplary such MIIM is described in U.S. Pat. No. 6,534,784, hereby incorporated by reference herein in its entirety. This type of diode is advantageous to an embodiment since it is composed of layers of metals and insulators. Such construction allows it to be manufactured in a way that is consistent with the manufacture of the resonant structures which are composed of layers of metal. For example, such a construction is described with respect to FIG. 2.

FIG. 2 is a cross-section view A-A′ of an exemplary antenna, substrate, and ground plane according to an embodiment of the present invention. FIG. 2 illustrates the substrate and embedded resonant structure elements 101 and 102 as resonant structure layer elements 201 and 202. In addition, resonant gaps 204 and 205 of substrate (S) material are shown between resonant structure layer elements 202 and 201 respectively and a ground plane 203. Exemplary materials for embodiments in the IR region include metals, such as Ni, Ag, or Au in the ground plane and resonant structures, and dielectrics transparent to IR, such as the polymide material Kapton. The resonant gap distance is preferably one-quarter (¼) wavelength as determined through peak frequency selection. Operation of resonant structure layer elements 201 and 202, resonant gaps 204 and 205, and ground plane 203 are described in U.S. Patent App. Pub. No. 2010/0284086, hereby incorporated by reference herein in its entirety.

FIG. 3 is a cross-section view B-B′ of an exemplary transfer structure 103 of co-planar strip 105 that is used for connecting antenna segments according to an embodiment of the present invention. As illustrated in FIG. 3, transfer structure 103 comprises layers of material that connect the two co-planar strip elements 105 (ultimately connected to resonant structure components 101 and 102 as shown in FIG. 1).

In an embodiment, a metal layer 304 forms the bottom layer of a MIIM diode structure serving as part of the transfer structure. A metal area 305 connects metal layer 304 to resonant structure layer element 202 thereby providing an electrical conduction path to antenna layer element 202. Onto metal layer 304 are deposited insulator layers 302. An exemplary such deposition of insulator layers is described in U.S. Pat. No. 6,534,784, hereby incorporated by reference herein in its entirety. Finally, a top layer of metal 301 is deposited to complete the electrical connection to 105/101 (see FIG. 1) and to complete the MIIM diode structure. Other transfer structures for providing impedance balancing are possible. For instance, ballistic diodes, geometric diodes, pin point diodes. Some of these other transfer structures may not need multiple layers or require different number of layers and different geometries for operation as described in this embodiment.

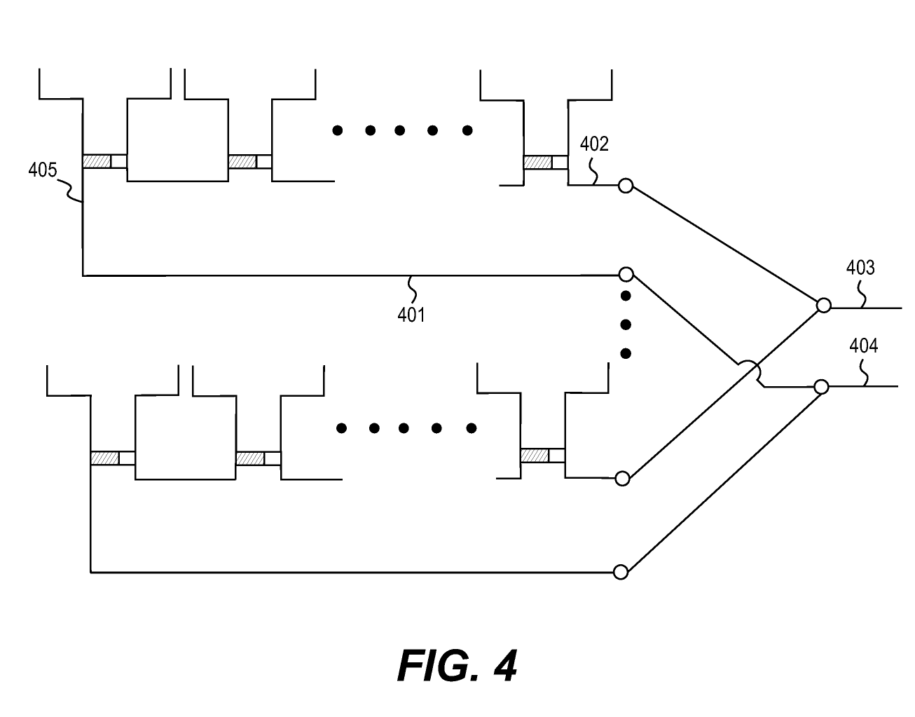

FIG. 4 is a schematic diagram of an exemplary bus illustrating interconnecting elements of an array according to an embodiment of the present invention. FIG. 4 shows sub-arrays 405 of the above described resonant structure elements with interconnecting leads 401 and 402 in series. Multiple sub-arrays 405 are interconnected in parallel to leads 403 and 404 to provide power to a device such as an electrical circuit, or other device or apparatus requiring electrical energy to operate.

This combination of multiple sub-arrays 405 can be embodied in large surface areas of material manufactured by inexpensive methods. For example, one such method of embodying the combination of multiple sub-arrays 405 into a large surface area of material is described for roll-to-roll production in U.S. Patent App. Pub. No. 2006/0283539, hereby incorporated by reference herein in its entirety. Such a structure can form the energy harvesting component for myriad embodiments, and is termed NEC film for purposes of identification and discussion herein. In an embodiment, the manufacturing process does not require doping.

FIG. 8 is a schematic diagram of an exemplary overall system diagram for providing power to devices or apparatus using a NEC film element 801. NEC film element 801 is interconnected to a power inverter 803. Power inverter 803 converts the DC output from NEC element 801 into power suitable to drive AC electronic equipment or be introduced into the electrical grid as available power at load 804.

In another embodiment of the invention the NEC film serves as the collector 602 in an MTPV system. FIG. 6 is a schematic illustration of a typical MTPV system, for example, as described in U.S. Patent App. Pub. 2010/0319749, hereby incorporated by reference herein in its entirety. In a conventional MTPV embodiment, emitter layer 601 is positioned at the optimum sub-micron gap distance G from window material 603 by spacers 605. Window layer 603 is then attached to collector 602 by an adhesive layer 604. When using NEC film as the collector layer 602 in an MTPV system according to an embodiment of the present invention, NEC film collector 602 can be configured in any of the embodiments described in the above-reference patent to best tune to the spectral content of the emitted radiation. Connection of collectors 602 into a comprehensive system such as shown in FIG. 8 and in the relationship to a heat source as shown in FIG. 9 are also embodied. The use of NEC film 602 in MTPV systems provides distinct advantages since the spectral output through the layers of the MTPV to the NEC film 602 may be matched by the frequency spectrum design of the resonant element arrays in the NEC layer. This optimizes efficiency and reduces energy loss to heat in the system.

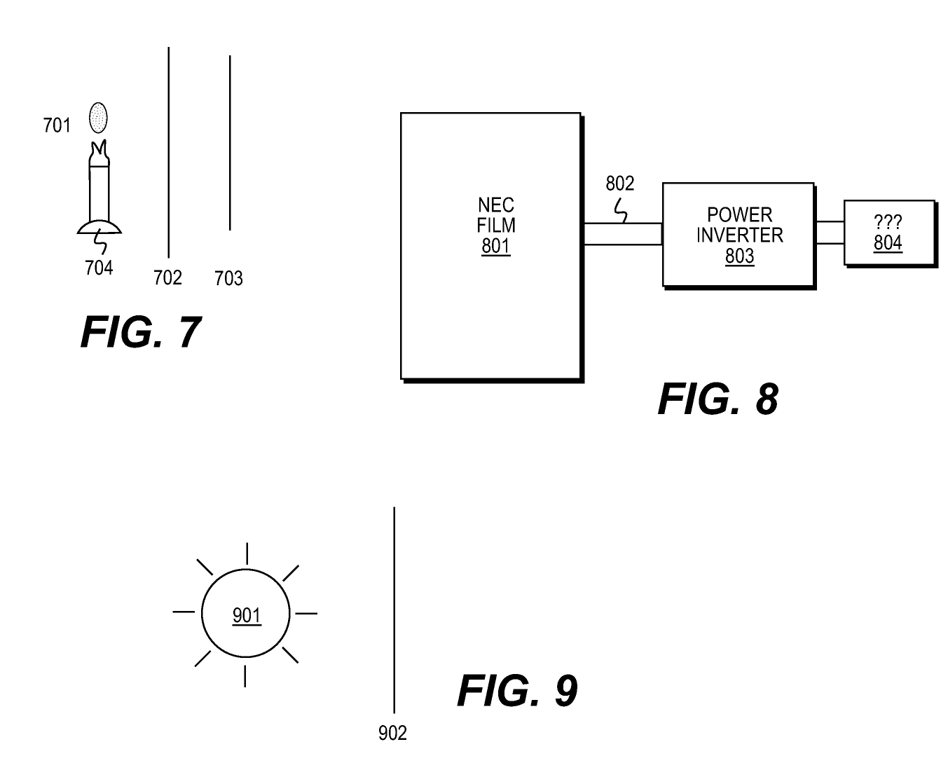

Since embodiments of the present invention can generate electricity from heat sources it is useful in a variety of applications. FIG. 7 illustrates a convention TPV device using NEC film 703 tuned to the spectral content of energy radiated by an emitter to harvest that energy and generate electricity. In a conventional TPV device, an emitter 701 is heated by a flame source 704 and produces radiation. The radiation produced by emitter 701 passes through a filter 702. Filter 702 is designed to pass only radiation in the collection band of a collector.

An advantage over a conventional TPV system offered by embodiments of the present invention is the ability to tune the arrays of resonant structures to the requirements of the source. For example, in an embodiment of a TPV using NEC film 703 as the collector, the source is the emitter 701. A hot emitter is a black body and its radiation spectra is well known. The design and modeling of the antenna structures to match incoming spectra are described in U.S. Pat. No. 7,792,644. Creating a collector 703 that fits the spectral output of the emitter 701 greatly reduces the requirements for filter 702 and may even obviate the need for 702 entirely. This is a significant improvement to conventional TPV systems.

Even an imperfect match of the collector's (703) frequency spectrum to the incoming spectra can yield a system that can perform effective harvesting since the ground plane 203 reflects unconverted radiation back to the emitter. In some embodiments, this reflected radiation mixes with that present in the emitter and is re-presented to the collector. In this way a simplified TPV system using only the collector described (NEC Film 801) is capable of harvesting significant percentages of available heat.

In another embodiment, heat is captured from a hot source 901 as shown in FIG. 9. FIG. 9 shows a view of a heat source 901 and a collector 902. The collector is an NEC film element as described above and part of a system as shown in FIG. 8. In this embodiment, radiation from the source 901 is collected for harvesting by collector 902. The resonant structures in 902 are tuned optimally to collect the radiation spectra of the heat source 901. The heat in this embodiment could emit from a variety of sources, for example, waste heat, direct solar, burned fuel sources such as coal, nuclear generated heat, etc. Since the temperature of these sources can vary considerably the ability to build NEC film with resonant structures tuned to the spectral output of the source is a big advantage over existing technologies.

The antennas in the antenna array of FIG. 4 can be configured (e.g., tuned) to provide any desired coverage of the frequency spectrum of a radiation source, such as a heat source. For example, an antenna tuned to the lowest frequency of the radiation's spectrum is able to harvest energy radiated at the low end of the spectrum, and an antenna tuned to the highest frequency of the number of frequencies is able to harvest energy radiated at the high end of the frequency spectrum. For example, in an embodiment, the antennas in the antenna array are configured to provide uniform coverage of the frequency spectrum.

However, because radiation source may emit radiation having a non-uniform distribution, the antennas in the antenna array may be configured to more accurately approximate the spectral distribution of the emitted radiation. For example, heat sources emit radiation in black body curve. As such, antennas in the antenna array may be configured to provide a non-uniform coverage of the frequency spectrum of a typical heat source.

For example, because a black body emits most of its energy in the central portions of the curve, in an embodiment, a higher number of antennas in the array are tuned to the frequencies near this central portion. In general, in an embodiment providing a non-uniform coverage of a radiation source's spectral distribution would devote a number of antennas at each frequency or frequency range of the radiation source in accordance with a histogram approximating the spectral distribution of the radiation source. Other radiation sources besides heat source may also benefit from a non-uniform distribution of the frequencies at which the antennas in the antenna array are tuned.

In addition, the antennas in these arrays can be distributed spatially so as to distribute the various frequency antennas evenly across the surface. Such distribution would avoid clustering of antennas of the same frequency and increase overall efficiency of the NEC film.

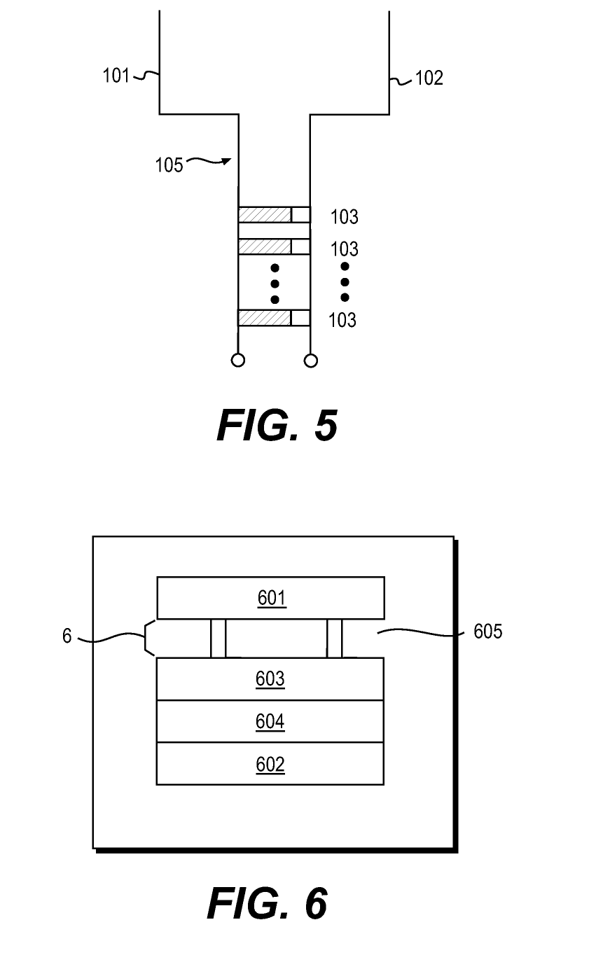

Matching the impedance of the resonant structure and the transfer structure is an important aspect of embodiments. FIG. 5 shows an additional method for matching these impedances. FIG. 5 is a schematic diagram of illustrating antenna having a co-planar strip connected by multiple transfer structures to reduce impedance/resistance. In the embodiment of FIG. 5, a plurality of transfer structures 103 is connected to resonant structure components 101 and 102 in parallel to reduce the impedance of the transfer structure. The number and position of these transfer structures required depends on the magnitude of the inherent impedance or resistance of the transfer structure. Multiple transfer structures 103 and the co-planar strip 105 may be manipulated in conjunction with each other to optimize the impedance match and other system properties. For instance, each transfer structure can pass a limited quantity of current and presents resistance and capacitance to the antenna circuit. Multiple transfer structures in parallel reduces the resistance and capacitance. The coplanar strip acts to add impedance to the transfer structure's (103) view of the antenna (102) to help balance as known to those familiar to antenna design art.

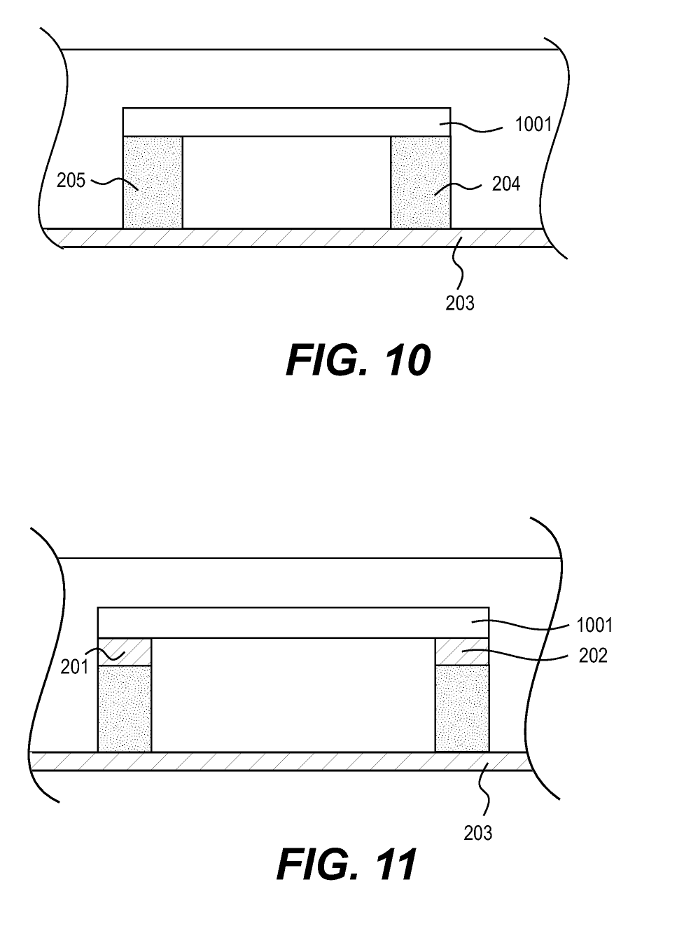

Other embodiments of the present invention may incorporate transfer structures differing in design. FIG. 10 shows an embodiment where the transfer structure 1001 is a single layer composed of the same material as the resonant structure. FIG. 11 shows an embodiment where the single layer transfer structure is composed of different material from the resonant structure. For instance, the resonant element 101 may best be made of Ag but the properties of Ni may be best to affect transfer through 103. This would necessitate multiple layers as described.

The foregoing disclosure of the preferred embodiments of the present invention has been presented for purposes of illustration and description. It is not intended to be exhaustive or to limit the invention to the precise forms disclosed. Many variations and modifications of the embodiments described herein will be apparent to one of ordinary skill in the art in light of the above disclosure. The scope of the invention is to be defined only by the claims appended hereto, and by their equivalents.

Further, in describing representative embodiments of the present invention, the specification may have presented the method and/or process of the present invention as a particular sequence of steps. However, to the extent that the method or process does not rely on the particular order of steps set forth herein, the method or process should not be limited to the particular sequence of steps described. As one of ordinary skill in the art would appreciate, other sequences of steps may be possible. Therefore, the particular order of the steps set forth in the specification should not be construed as limitations on the claims. In addition, the claims directed to the method and/or process of the present invention should not be limited to the performance of their steps in the order written, and one skilled in the art can readily appreciate that the sequences may be varied and still remain within the spirit and scope of the present invention.

What is claimed:

1. A system to convert electromagnetic radiation to electrical energy, comprising:
a resonant structure element that is tuned to resonate at a resonant frequency included in a frequency range of the electromagnetic radiation, wherein electrical energy is stimulated in the resonant element in the presence of electromagnetic radiation having a frequency at or near the resonant frequency; and
a transfer structure to convert the stimulated electrical energy to direct current.

2. The system of claim 1, further comprising a co-planar strip, coupled to the resonant element and the transfer structure to provide impedance matching between the resonant element and the transfer structure.

3. The system of claim 1, wherein the transfer structure is a MIIM diode.

4. The system of claim 1, further comprising at least one additional transfer structure.

5. The system of claim 1, where in the transfer structure comprises at least one diode wherein the diode and resonant element each comprises at least one layer such that the resonant element and diode can be manufactured using the same process.

6. The system of claim 5, wherein the manufacturing process is a roll-to-roll process.

7. The system of claim 5, wherein the manufacturing process does not require doping.

8. The system of claim 1, further comprising a ground plane to reflect radiation not absorbed by the resonant structure back toward the resonant structure.

9. A system to convert electromagnetic radiation to electrical energy, comprising an array of nanoantennae to capture energy in the spectral range of the electromagnetic radiation and convert the captured radiation to electrical energy.

10. The system of claim 9, wherein the array of nanoantennae is configured to provide uniform coverage over the frequency spectrum of the electromagnetic radiation.

11. The system of claim 9, wherein the array of nanoantennae is configured to provide non-uniform coverage over the frequency spectrum of the electromagnetic radiation.

12. The system of claim 9, wherein the nanoantenna array is configured to provide coverage of the frequency spectrum electromagnetic radiation in approximation to the frequency spectral distribution of the electromagnetic radiation.

13. The system of claim 9, wherein each nanoantenna comprises:
a resonant element pair comprising a first resonant element that is tuned to resonate at a first resonant frequency included in a frequency range of the electromagnetic radiation and a second resonant element that is tuned to resonate at a second resonant frequency included in the frequency range of the electromagnetic radiation, wherein electrical energy is stimulated in the first resonant element in the presence of electromagnetic radiation having a frequency at or near the first resonant frequency and electrical energy is stimulated in the second resonant element in the presence of electromagnetic radiation having a frequency at or near the second resonant frequency;
a first co-planar strip coupled to the first resonant elements;
a second co-planar strip coupled to the second resonant element; and
a transfer structure to coupled to the first and second co-planar strips to convert the electrical energy stimulated in each first and second resonant element of each resonant element pair to DC current.

14. The system of claim 9, wherein the nanoantenna array is incorporated into a film.

15. The system of claim 9, further comprising an electrical apparatus to which the nanoantenna array provides a source of electrical energy.

16. The system of claim 9, further comprising an electrical energy grid to which the nanoantenna array provides a source of electrical energy.

17. The system of claim 9, further comprising a ground plane to reflect radiation not absorbed by the antenna array back toward the antenna array.

18. The system of claim 9, wherein the system is a TPV system, comprising a heat source and a collector.

19. The system of claim 17, wherein the collector is a NEC film collector.

20. The system of claim 17, wherein there is no filter to ensure electromagnetic radiation of an appropriate frequency impinges on the collector.

21. A method for converting electromagnetic radiation to electrical energy, comprising:
providing a resonant structure element that is tuned to resonate at a resonant frequency included in a frequency range of the electromagnetic radiation, wherein electrical energy is stimulated in the resonant structure element in the presence of electromagnetic radiation having a frequency at or near the resonant frequency; and
providing a transfer structure to convert the stimulated electrical energy to direct current.

22. The method of claim 21, further comprising coupling a co-planar strip to the resonant structure element and the transfer structure to provide impedance matching between the resonant structure element and the transfer structure.

23. The method of claim 21, wherein the transfer structure is a MIIM diode.

24. The method recited in claim 21, further comprising at least one additional transfer structure.

25. The method of claim 21, where in the transfer structure comprises at least one diode wherein the diode and resonant structure element each comprises at least one layer such that the resonant element and diode can be manufactured using the same process.

26. The method of claim 25, wherein the manufacturing process is a roll-to-roll process.

27. The method of claim 25, wherein the manufacturing process does not require doping.

28. A method for converting electromagnetic radiation to electrical energy, comprising:
configuring a nanoantenna array comprising a plurality of nanoantennae to capture energy in the spectral range of the electromagnetic radiation; and
converting the captured radiation to electrical energy.

29. The method of claim 28, further comprising configuring the nanoantenna array to provide uniform coverage over the frequency spectrum electromagnetic radiation.

30. The method of claim 28, further comprising configuring the nanoantenna array to provide non-uniform coverage of the frequency spectrum electromagnetic radiation.

31. The method of claim 28, further comprising configuring the nanoantenna array to provide coverage of the frequency spectrum electromagnetic radiation in approximation to the frequency spectral distribution of the electromagnetic radiation.

32. The method of claim 28, further comprising incorporating the nanoantenna array into a film.

33. The method of claim 28, further comprising sourcing an electrical apparatus with electrical energy using the nanoantenna array.

34. The system of claim 28, further comprising sourcing an electrical energy grid with electrical energy using the nanoantenna array.

35. The method of claim 21, further comprising a ground plane to reflect radiation not absorbed by the antenna array back toward the antenna array.

36. The method of claim 21, wherein the system is a TPV system, comprising a heat source and a collector.

37. The method of claim 36, wherein the collector is a NEC film collector.

38. The method of claim 36, wherein there is no filter to ensure electromagnetic radiation of an appropriate frequency impinges on the collector.

39. A TPV system, comprising:
a. an emitter that sources radiation; and
b. a collector that comprises a nanoantenna array to capture energy in the spectral range of the electromagnetic radiation and convert the captured radiation to electrical energy.

40. The TPV system of claim 39, wherein the collector is a NEC film.

41. The TPV system of claim 39, wherein there is no filter to focus the emitted radiation.
